(19) United States
(12) Patent Application Publication
(10) Pub. No.: US 2025/0214785 A1
(43) Pub. Date: Jul. 3, 2025

(54) END EFFECTOR AND SUBSTRATE TRANSFER APPARATUS

(71) Applicant: SEMES CO., LTD., Cheonan-si (KR)

(72) Inventors: Chan Young CHOI, Suwon-si (KR); Sang Oh KIM, Seoul (KR); Jae Won CHOI, Osan-si (KR); Hyung Bin IM, Seoul (KR); Sang Hyeop LEE, Hwaseong-si (KR); Sun Wook JUNG, Hwaseong-si (KR)

(73) Assignee: SEMES CO., LTD., Cheonan-si (KR)

(21) Appl. No.: 19/001,731

(22) Filed: Dec. 26, 2024

(30) Foreign Application Priority Data
Dec. 29, 2023 (KR) 10-2023-0197509

(51) Int. Cl. B65G 47/90

(52) U.S. Cl. CPC B65G 47/90

(57) ABSTRACT

A substrate transfer apparatus is provided. The substrate transfer apparatus includes: a robot unit installed at an end of an arm and having an end effector supporting a substrate; and a moving unit moving the robot unit, wherein the end effector includes: a body; supports installed on the body and supporting an underside of the substrate; and spark gaps installed on the body and inducing discharge to the outside of the body when charge accumulating on the substrate reaches a threshold value.

### CROSS-REFERENCE TO RELATED APPLICATIONS

This application claims priority to and the benefit of Korean Patent Application No. 10-2023-0197509 filed in the Korean Intellectual Property Office on Dec. 29, 2023, the entire contents of which are incorporated herein by reference.

### TECHNICAL FIELD

The present invention relates to an end effector and a substrate transfer apparatus having the end effector.

### BACKGROUND ART

A semiconductor manufacturing process is a process of manufacturing a semiconductor product that can process electric signals, and includes a processing process (front-end processing) that forms a pattern on a wafer through processing procedures such as oxidation, photolithography, etching, ion implantation, and deposition and a packaging step (back-end process) that manufactures a semiconductor package in a finished form through procedures such as dicing, die bonding, wiring, molding, marking, and testing for a wafer with a pattern. A semiconductor manufacturing process is performed at semiconductor manufacturing facilities for performing respective processes and the semiconductor manufacturing facilities are each configured to performing a process on a loaded wafer and then discharge the wafer. Semiconductor manufacturing facilities have one or more wafer conveying robots for conveying wafers.

However, a wafer conveying robot may partially damage nano-scale patterning on a wafer surface by triboelectric charging that is generated due to contact of different kinds of materials. In particular, in the case of a wafer conveying robot of a non-contact drive wafer conveying robot such as magnetic levitation, the possibility of electrostatic charging is high when the robot is driven, and when there is no appropriate discharge measure against electrostatic charging, there is a high risk of user electric shock accidents and component damage due to spark generation in components of a drive power conversion unit.

### SUMMARY OF THE INVENTION

An objective of the present disclosure is to provide an end effector that can neutralize the charge that charges the surface of a substrate, and a substrate transfer apparatus having the end effector.

An objective of the present disclosure is to provide an end effector that can prevent damage to a substrate by inducing discharge to the opposite side of a substrate when electrostatic charge accumulated in the substrate reaches a threshold voltage, and a substrate transfer apparatus having the end effector.

The objectives of the present invention are not limited thereto and other objectives not stated herein may be clearly understood by those skilled in the art from the following description.

According to an aspect of the present disclosure, there may be provided a substrate transfer apparatus including: a robot unit installed at an end of an arm and having an end effector supporting a substrate; and a moving unit moving the robot unit, wherein the end effector includes: a body; supports installed on the body and supporting an underside of the substrate; and spark gaps installed on the body and inducing discharge to the outside of the body when charge accumulating on the substrate reaches a threshold value.

Further, the spark gaps may have a pointed leading end to concentrate charge around the spark gaps and induce discharge.

Further, the spark gaps may have a circular cross-section and may have a shape in which a size of the cross-section gradually decreases toward an end and the leading end is positioned at a center.

Further, the body may include: a base part connected to the end of the arm; a finger part extending from the base part and positioned outside from an edge of the substrate to surround a seating area in which the substrate is positioned, and the supports may be installed on an inner surface of the finger part with predetermined gaps like surrounding the seating area.

Further, the spark gaps may be horizontally installed on an outer surface of the finger part and are provided such that the leading end faces the opposite direction of the seating area.

Further, the substrate transfer apparatus may further include a corona discharge electrode producing ions through corona discharge and neutralizing static electricity of a substrate by the ions.

Further, the corona discharge electrode may be provided as a discharge pin having a pointed leading end.

Further, the leading end of the discharge pin may be positioned higher than a pattern surface of the substrate.

Further, the moving unit may be driven in a wireless power transmission type.

According to another aspect of the present disclosure, there may be provided an end effector including: a body; and spark gaps installed on the body and inducing discharge to the outside of the body when charge accumulating on the substrate reaches a threshold value.

Further, the spark gaps may have a pointed leading end to concentrate charge around the spark gaps and induce discharge.

Further, the spark gaps may have a circular cross-section and may have a shape in which a size of the cross-section gradually decreases toward an end and the leading end is positioned at a center.

Further, the body may include: a base part connected to an end of the arm; a finger part extending from the base part and positioned outside from an edge of the substrate to surround a seating area in which the substrate is positioned; and supports installed on an inner surface of the finger part with predetermined gaps like surrounding the seating area.

Further, the spark gaps may be horizontally installed on an outer surface of the finger part and are provided such that the leading end faces the opposite direction of the seating area.

Further, the substrate transfer apparatus may further include a corona discharge electrode producing ions through corona discharge and neutralizing static electricity of a substrate by the ions.

Further, the corona discharge electrode may be provided as a discharge pin having a pointed leading end.

Further, the leading end of the discharge pin may be positioned higher than a pattern surface of the substrate.

According to another aspect of the present disclosure, there may be provided a substrate transfer apparatus including: a robot unit installed at an end of an arm and having an end effector supporting a substrate; and a moving unit driven in a wireless power transmission type to move the robot unit, wherein the end effector includes: a body having a finger part extending from the base part connected to the end of the arm and positioned outside from an edge of the substrate to surround a seating area in which the substrate is positioned; supports installed on an inner surface of the finger part with predetermined gaps like surrounding the seating area; spark gaps installed on an outer surface of the finger part and inducing discharge to the outside of the body when chare accumulating on the substrate reaches a threshold value; and a corona discharge electrode installed on a top of the finger part, producing ions through corona discharge, and neutralizing static electricity of the substrate by the ions.

Further, the corona discharge electrode may be provided as a discharge pin having a pointed leading end, the spark gaps may have a pointed leading end to concentrate charge around the spark gaps and induce discharge, and the spark gaps may be horizontally installed on an outer surface of the finger part and may be provided such that the pointed leading end faces the opposite direction of the seating area.

Further, the leading end of the discharge pin may be positioned higher than a pattern surface of the substrate.

According to an embodiment of the present disclosure, the corona discharge electrode produces space charge and neutralizes charge accumulated on an electrified body (end effector, patterned substrate) (charge neutralization function), thereby reducing the potential of the electrified body simply and easily at a low cost and reducing the potential difference between substrates. Accordingly, there is an effect of being able to decrease the risk of arcing.

According to an embodiment of the present invention, spark gaps (electrodes) induce discharge to the opposite side of the seating area of a substrate when a threshold voltage is reached due to overcharge of the substrate, whereby there is a specific effect of being able to prevent damage to the components of a substrate.

Effects of the present invention are not limited to those described above and effects not stated above will be clearly understood to those skilled in the art from the specification and the accompanying drawings.

### BRIEF DESCRIPTION OF THE DRAWINGS

FIG. 1 is a view showing a magnetic levitation-type substrate conveying apparatus according to an embodiment of the present invention.

FIG. 2 is a perspective view showing an end effect of the robot unit shown in FIG. 1.

FIG. 3 is a plan view of the end effector shown in FIG. 2.

FIG. 4 is an enlarged view showing main parts of FIG. 2.

FIG. 5 is a view showing the height difference between a corona discharge electrode and a substrate.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

The specification provides examples of the present disclosure. Further, the description provides an embodiment of the present disclosure and the present disclosure may be used in other various combination, changes, and environments. That is, the present invention may be changed or modified within the scope of the present invention described herein, a range equivalent to the description, and/or within the knowledge or technology in the related art. The embodiment shows an optimum state for achieving the spirit of the present invention and may be changed in various ways for the detailed application fields and use of the present invention. Therefore, the detailed description of the present disclosure is not intended to limit the present disclosure in the embodiment. Further, the claims should be construed as including other embodiments.

The present invention provides a substrate transfer apparatus that can improve a potential difference by generating a space charge between a substrate and an end effector and can prevent damage to the components of the substrate by inducing discharge to the opposite side of the seating area of the substrate when a threshold voltage is reached due to overcharging of the substrate.

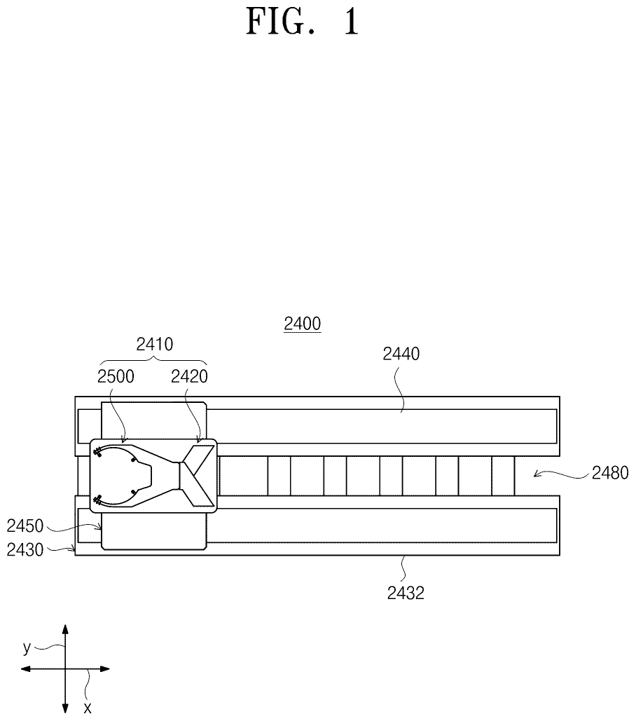

FIG. 1 is a view showing a magnetic levitation-type substrate conveying apparatus according to an embodiment of the present invention.

Referring to FIG. 1, a substrate conveying apparatus 2400 may include a robot unit 2410 and a moving unit 2420. The substrate conveying apparatus 2400 can be applied to various apparatuses for performing semiconductor processing processes such as etching, applying, developing, and deposition.

The robot unit 2410 includes an arm 2412 and an end effector 2500 supporting a substrate to transfer the substrate. The robot unit 2410 is installed on a moving plate 2460. The robot unit can be moved by a moving unit.

The moving unit 2420 may be a device for moving the robot unit 2410 in a magnetic levitation type in a first direction. For example, the moving unit 2420 may include a rail structure 2430, a mover that can move in a non-contact state with the rail structure, and a linear motor. In this configuration, the linear motor is an actuator providing propulsion to the moving plate 2460. The linear motor may be a Linear Synchronous Motor (LSM) using a coil (electromagnet).

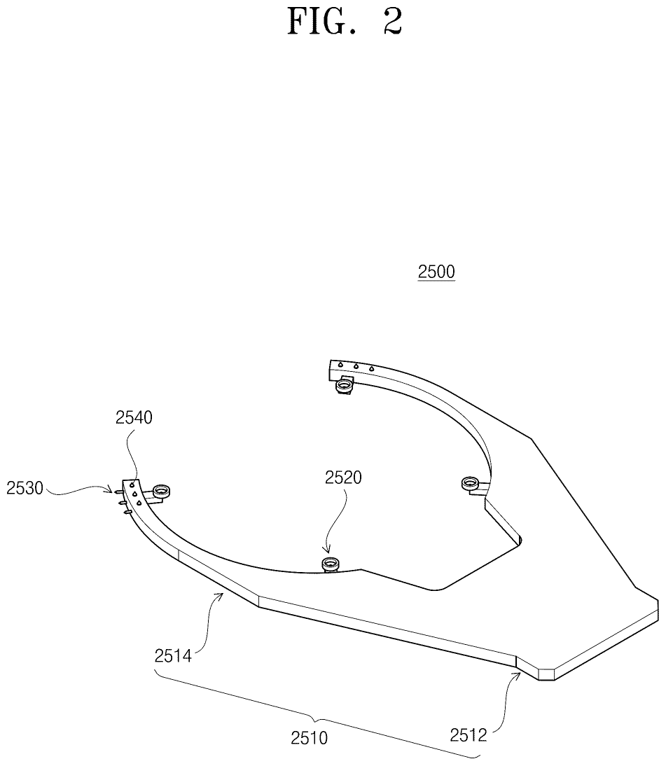

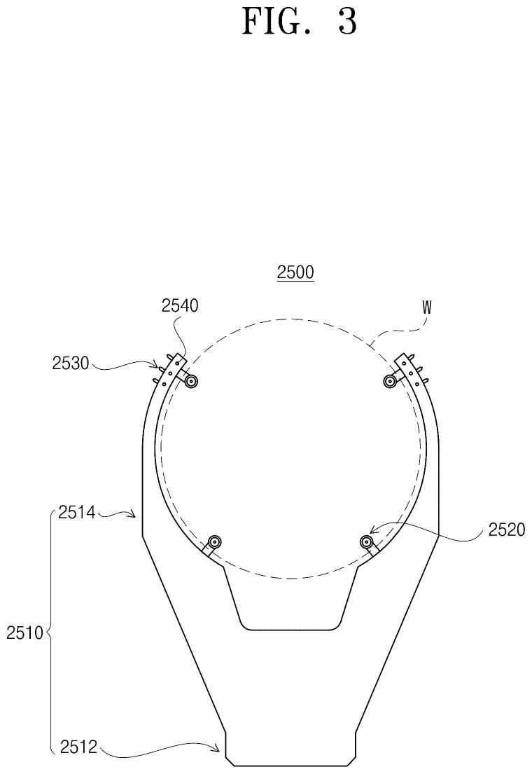

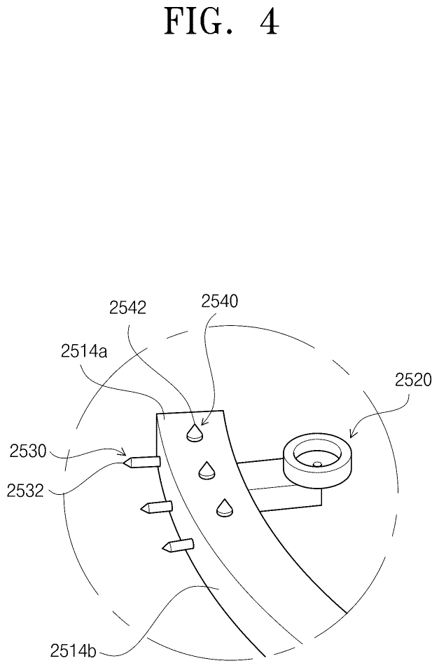

FIG. 2 is a perspective view showing an end effect of the robot unit shown in FIG. 1, FIG. 3 is a plan view of the end effector shown in FIG. 2, and FIG. 4 is an enlarged view showing main parts of FIG. 2.

Referring to FIG. 2 to FIG. 4, the end effector 2500 may include a body 2510, supports 2520, spark gaps 2530, and corona discharge electrodes 2540.

The body 2510 may include a base part 2512 and a finger part 2514. The base part 2512 is a part connected to an arm 2412 (shown in FIG. 1). The finger part 2514 extends from the base part 2512. The finger part 2514 is formed substantially in a horseshoe shape having an inner diameter larger than the diameter of a substrate to surround the seating area in which a substrate W is placed. However, the shape of the body 2510 is not limited thereto.

The supports 2520 are installed inward from the body 2510 with gaps therebetween like surrounding the seating area. The supports 2520 support the underside of a substrate W. For example, the body 2510 has a vacuum channel (not shown) therein and the vacuum channel may be connected with a vacuum pump (not shown) through a vacuum line. The supports 2520 are connected to the vacuum channel, so they can suction and hold the underside of a substrate W using vacuum. Although the end effector 2500 is shown to have four supports 2520 in this embodiment, but this is not intended to be limiting. It is preferable for the end effector 2500 to have at least three or more supports 2520 that can maintain a substrate W as horizontally as possible and evenly distribute the weight of the substrate W.

A plurality of spark gaps 2530 may be installed on the body 2510. The spark gap 2530 functions as a type of Transient Voltage Suppressor (TVS) Diode. When a substrate has a high voltage due to continuous friction, breakdown, that is, discharge can be induced toward surrounding devices (e.g., a cooling plate). That is, the spark gaps 2530 induce discharge to the outside of the body 2510 when the charge accumulated on the substrate W reaches a threshold value. The spark gaps 2530 have a pointed leading end 2532 to concentrate the charge around the spark gaps and induce discharge. For example, the spark gaps 2530 may have a circular cross-section and may have a shape in which the size of the cross-section gradually decreases toward the end and the leading end 2532 is positioned at the center. It is preferable that the spark gaps 2530 are horizontally installed on the outer surface 2514b of the finger 2514 to minimize damage to a substrate in discharging and are provided such that the leading end 2532 faces the opposite direction of the seating area where a substrate is positioned.

Accordingly, electrostatic charges around the spark gaps 2530 are induced toward the spark gaps 2530 and concentrated at the leading edges 2532. When the threshold voltage is reached, breakdown, that is, discharge is induced toward surrounding devices (e.g., a cooling plate), whereby it is possible to suppress arcing on a substrate W. Further, it is possible to minimize damage to a substrate when discharging at the spark gaps 2530.

A plurality of corona discharge electrodes 2540 may be installed on the top 2514a of the finger 2514 to be positioned adjacent to a substrate W. The corona discharge electrodes 2540 ionize the atmosphere around a substrate through corona discharge and ions produced in this way spread to the top of the substrate, thereby neutralizing static electricity of the substrate W. The corona discharge electrodes 2540 all have the same height in the figures, but they are not intended to be limiting and, if necessary, the corona discharge electrodes may be provided to have different heights.

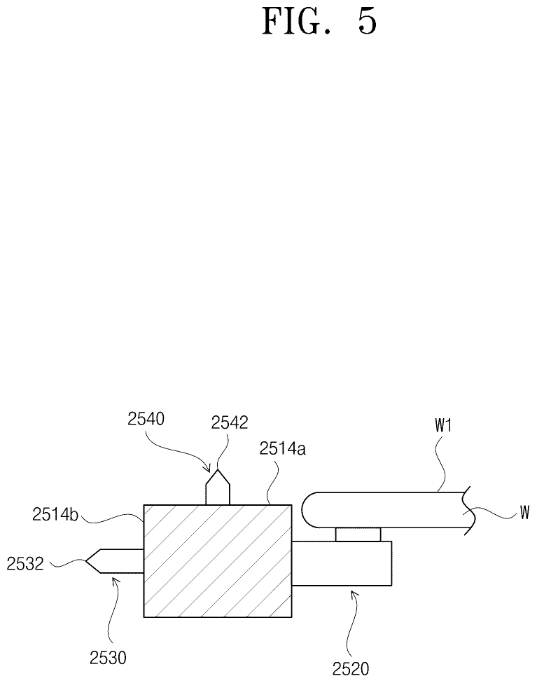

The corona discharge electrode 2540 may be provided in a pin shape having a pointed leading end 2542. It is preferable that the leading end 2542 of the corona discharge electrode 2540, as shown in FIG. 5, is positioned higher than a pattern surface W1 of a substrate W so the ions produced by corona discharge can be easily provided to the pattern surface of the substrate W. The corona discharge electrodes 2540 have electrode design that can secure 3.6 [MV/m] that is electric field intensity at which corona discharge can be generated. As another example, the corona discharge electrodes 2540 receives power from a power supply (not shown) and can produce ions.

The corona discharge electrodes 2540 may be disposed on the finger 2514 at which the electric field intensity is the most concentrated. In the case of a typical ionizer, continuous maintenance is required and ion balance must be adjusted. However, according to the corona discharge electrodes 2540 of the present invention, corona discharge is performed only when a substrate is sufficiently charged, so there is a unique advantage of requiring no maintenance.

Meanwhile, the spark gaps 2530 and the corona discharge electrodes 2540 may be materials having high resistance at the level of 6˜200 MΩ.

According to the end effector 2500 of the robot unit having the configuration described above, excess charge in which a lot of charges of (+) or (−) polarity existing between semiconductor devices accumulate on any one of the end effector or a substrate is generated by friction due to contact with and separation from the substrate W. In other words, a great number of charges with (+) polarity and (−) polarity exist between semiconductor devices, and when the end effector 2500 approaches or comes in contact with the area therebetween, the charges with (+) polarity and (−) polarity that have not been moved are moved, so polarized charges are produced and static electricity is generated. When the charges accumulates on the end effector 2500 reach the threshold voltage, the spark gaps 2530 induces discharge to the opposite side of a substrates, thereby being able to prevent damage to the substrate.

The specification provides examples of the present disclosure. Further, the description provides an embodiment of the present disclosure and the present disclosure may be used in other various combination, changes, and environments. That is, the present invention may be changed or modified within the scope of the present invention described herein, a range equivalent to the description, and/or within the knowledge or technology in the related art. The embodiment shows an optimum state for achieving the spirit of the present invention and may be changed in various ways for the detailed application fields and use of the present invention. Therefore, the detailed description of the present disclosure is not intended to limit the present disclosure in the embodiment. Further, the claims should be construed as including other embodiments.

What is claimed is:

1. A substrate transfer apparatus, comprising:
a robot unit installed at an end of an arm and having an end effector supporting a substrate; and
a moving unit moving the robot unit,
wherein the end effector comprises:
a body;
supports installed on the body and supporting an underside of the substrate; and
spark gaps installed on the body and inducing discharge to the outside of the body when charge accumulating on the substrate reaches a threshold value.

2. The substrate transfer apparatus of claim 1, wherein the spark gaps have a pointed leading end to concentrate charge around the spark gaps and induce discharge.

3. The substrate transfer apparatus of claim 2, wherein the spark gaps have a circular cross-section and have a shape in which a size of the cross-section gradually decreases toward an end and the leading end is positioned at a center.

4. The substrate transfer apparatus of claim 2, wherein the body comprises:
a base part connected to the end of the arm; and
a finger part extending from the base part and positioned outside from an edge of the substrate to surround a seating area in which the substrate is positioned, and
the supports are installed on an inner surface of the finger part with predetermined gaps like surrounding the seating area.

5. The substrate transfer apparatus of claim 4, wherein the spark gaps are horizontally installed on an outer surface of the finger part and are provided such that the leading end faces the opposite direction of the seating area.

6. The substrate transfer apparatus of claim 2, wherein the end effector further comprises a corona discharge electrode producing ions through corona discharge and neutralizing static electricity of a substrate by the ions.

7. The substrate transfer apparatus of claim 6, wherein the corona discharge electrode is provided as a discharge pin having a pointed leading end.

8. The substrate transfer apparatus of claim 7, wherein the leading end of the discharge pin is positioned higher than a pattern surface of the substrate.

9. The substrate transfer apparatus of claim 1, wherein the moving unit is driven in a wireless power transmission type.

10. An end effector supporting a substrate, comprising:
a body; and
spark gaps installed on the body and inducing discharge to the outside of the body when charge accumulating on the substrate reaches a threshold value.

11. The end effector of claim 10, wherein the spark gaps have a pointed leading end to concentrate charge around the spark gaps and induce discharge.

12. The end effector of claim 11, wherein the spark gaps have a circular cross-section and have a shape in which a size of the cross-section gradually decreases toward an end and the leading end is positioned at a center.

13. The end effector of claim 12, wherein the body comprises:
a base part connected to an end of the arm;
a finger part extending from the base part and positioned outside from an edge of the substrate to surround a seating area in which the substrate is positioned; and
supports installed on an inner surface of the finger part with predetermined gaps like surrounding the seating area.

14. The end effector of claim 13, wherein the spark gaps are horizontally installed on an outer surface of the finger part and are provided such that the leading end faces the opposite direction of the seating area.

15. The end effector of claim 11, further comprising a corona discharge electrode producing ions through corona discharge and neutralizing static electricity of a substrate by the ions.

16. The end effector of claim 15, wherein the corona discharge electrode is provided as a discharge pin having a pointed leading end.

17. The end effector of claim 16, wherein the discharge pin is positioned higher than a pattern surface of the substrate.

18. A substrate transfer apparatus, comprising:
a robot unit installed at an end of an arm and having an end effector supporting a substrate; and
a moving unit driven in a wireless power transmission type to move the robot unit,
wherein the end effector comprises:
a body having a finger part extending from the base part connected to the end of the arm and positioned outside from an edge of the substrate to surround a seating area in which the substrate is positioned;
supports installed on an inner surface of the finger part with predetermined gaps like surrounding the seating area;
spark gaps installed on an outer surface of the finger part and inducing discharge to the outside of the body when chare accumulating on the substrate reaches a threshold value; and
a corona discharge electrode installed on a top of the finger part, producing ions through corona discharge, and neutralizing static electricity of the substrate by the ions.

19. The substrate transfer apparatus of claim 18, wherein the corona discharge electrode is provided as a discharge pin having a pointed leading end,
the spark gaps have a pointed leading end to concentrate charge around the spark gaps and induce discharge, and
the spark gaps are horizontally installed on an outer surface of the finger part and are provided such that the pointed leading end faces the opposite direction of the seating area.

20. The substrate transfer apparatus of claim 19, wherein the leading end of the discharge pin is positioned higher than a pattern surface of the substrate.
